(19) United States
(12) Patent Application Publication
(10) Pub. No.: US 2013/0221423 A1
(43) Pub. Date: Aug. 29, 2013

(54) NONVOLATILE SEMICONDUCTOR MEMORY DEVICE AND METHOD FOR MANUFACTURING SAME

(71) Applicants: Kaori Kawasaki, Kanagawa-Ken (JP); Yoshiaki Fukuzumi, Kanagawa-ken (JP); Naoki Yasuda, Kanagawa-ken (JP); Hideaki Aochi, Kanagawa-ken (JP)

(72) Inventors: Kaori Kawasaki, Kanagawa-Ken (JP); Yoshiaki Fukuzumi, Kanagawa-ken (JP); Naoki Yasuda, Kanagawa-ken (JP); Hideaki Aochi, Kanagawa-ken (JP)

(73) Assignee: Kabushiki Kaisha Toshiba, Tokyo (JP)

(21) Appl. No.: 13/599,420

(22) Filed: Aug. 30, 2012

(30) Foreign Application Priority Data
Feb. 29, 2012 (JP) 2012-044415

(51) Int. Cl. H01L 29/788; H01L 21/20

(52) U.S. Cl. 257/321; 438/478; 257/E29.3; 257/E21.09

(57) ABSTRACT

According to one embodiment, a nonvolatile semiconductor memory device includes an underlayer and a stacked body. The stacked body includes control gate layers and insulating layers. The device includes a channel body layer penetrating through the stacked body, and the control gate layers and the insulating layers are stacked in the stacking direction, a floating gate layer provided between each of the plurality of control gate layers and the channel body layer. The device includes a block insulating layer provided between each of the plurality of control gate layers and the floating gate layer, and includes a tunnel insulating layer provided between the channel body layer and the floating gate layer. A length of a boundary between the floating gate layer and the block insulating layer is shorter than a length of a boundary between the floating gate layer and the tunnel insulating layer.

### CROSS-REFERENCE TO RELATED APPLICATIONS

This application is based upon and claims the benefit of priority from Japanese Patent Application No. 2012-044415, filed on Feb. 29, 2012; the entire contents of which are incorporated herein by reference.

### FIELD

Embodiments described herein relate generally to a nonvolatile semiconductor memory and a method for manufacturing the same.

### BACKGROUND

These days, to increase the integration degree of a nonvolatile semiconductor memory device, a structure in which memory cells in the nonvolatile semiconductor memory device are three-dimensionally arranged is proposed. As a structure in which memory cells are three-dimensionally arranged, there is one using a transistor of a circular columnar structure. In the semiconductor memory device using the transistor of a circular columnar structure, multiply stacked conductive layers as gate electrodes and a columnar semiconductor layer in a pillar shape are provided. The columnar semiconductor layer functions as a channel body layer of the transistor. An ONO (oxide-nitride-oxide) layer is provided around the columnar semiconductor layer. A configuration including the multiply stacked conductive layers, the columnar semiconductor layer, and the ONO layer is called a memory string.

A memory cell of a floating gate structure is drawing attention nowadays in place of the ONO structure, because of its good data retention, resistant to the occurrence of a threshold variation after writing, and a relatively high operating speed. For the floating gate, it is desired to suppress the variation in its film thickness furthermore with the downsizing of the memory cell progresses.

### BRIEF DESCRIPTION OF THE DRAWINGS

FIG. 1 is a schematic perspective view of a memory cell array of a nonvolatile semiconductor memory device according to a first embodiment;

FIG. 2 is an enlarged cross-sectional view of a portion of the memory cells according to the first embodiment;

FIG. 3A to FIG. 8 are schematic cross-sectional views for describing manufacturing processes of the nonvolatile semiconductor memory device according to the first embodiment;

FIG. 9A to FIG. 10B are schematic cross-sectional views for describing manufacturing processes of a memory cell according to a comparative example;

FIGS. 11A and 11B are schematic cross-sectional views for describing manufacturing processes of a nonvolatile semiconductor memory device according to a second embodiment;

FIG. 12 is an enlarged cross-sectional view of a portion of memory cells according to a third embodiment;

FIG. 13A to FIG. 15C are schematic cross-sectional views for describing manufacturing processes of a nonvolatile semiconductor memory device according to the third embodiment;

FIG. 16A to FIG. 17B are schematic cross-sectional views for describing manufacturing processes of a nonvolatile semiconductor memory device according to a modification example of the third embodiment; and

FIG. 18 is a schematic perspective view for describing a nonvolatile semiconductor memory device according to a fourth embodiment.

### DETAILED DESCRIPTION

In general, according to one embodiment, a nonvolatile semiconductor memory device includes an underlayer. The device includes a stacked body provided on the underlayer and including a plurality of control gate layers and a plurality of insulating layers, and each of the plurality of control gate layers and each of the plurality of insulating layers being stacked alternately. The device includes a channel body layer penetrating through the stacked body in a stacking direction, and the plurality of control gate layers and the plurality of insulating layers are stacked in the stacking direction. The device includes a floating gate layer provided between each of the plurality of control gate layers and the channel body layer. The device includes a block insulating layer provided between each of the plurality of control gate layers and the floating gate layer. And the device includes a tunnel insulating layer provided between the channel body layer and the floating gate layer.

A length of a boundary between the floating gate layer and the block insulating layer is shorter than a length of a boundary between the floating gate layer and the tunnel insulating layer in a cut surface obtained by cutting the channel body layer in the stacking direction along a central axis of the channel body layer.

Hereinbelow, embodiments are described with reference to the drawings. In the following description, identical components are marked with the same reference numerals, and a description of components once described is omitted as appropriate.

### First Embodiment

An overview of a nonvolatile semiconductor memory device according to a first embodiment will now be described.

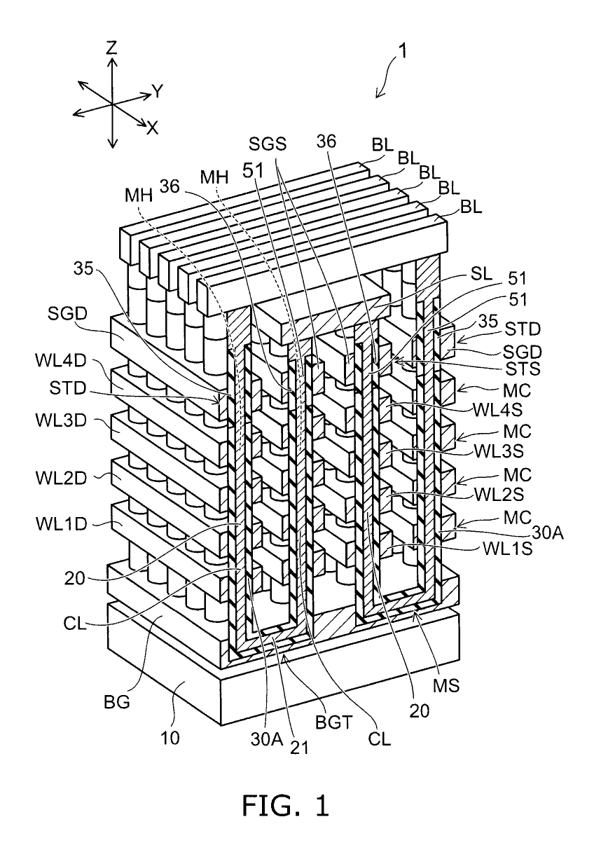

FIG. 1 is a schematic perspective view of a memory cell array of the nonvolatile semiconductor memory device according to the first embodiment.

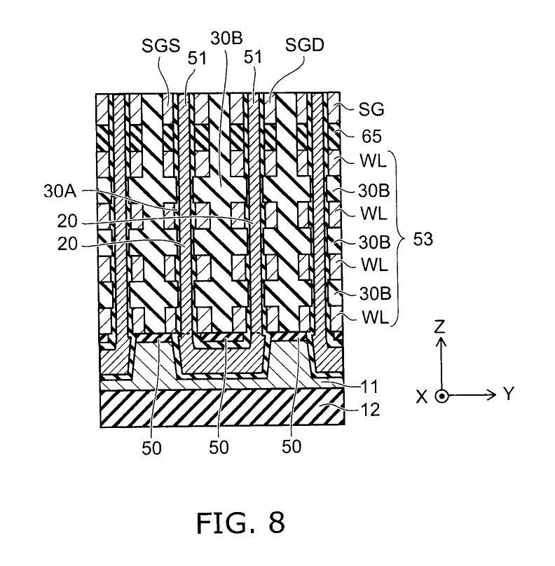

In FIG. 1, for easier viewing of the drawing, the insulating portions other than an insulating film formed on the inner wall of a memory hole MH are omitted. The insulating portions are described using FIG. 8 that is a schematic cross-sectional view of the same memory cell array.

In FIG. 1, for convenience of description, an XYZ orthogonal coordinate system is used. In the coordinate system, two directions parallel to the major surface of a substrate 10 and orthogonal to each other are defined as the X direction and the Y direction, and the direction orthogonal to both the X direction and the Y direction is defined as the Z direction.

A nonvolatile semiconductor memory device 1 of the first embodiment can perform the erasing and writing of data electrically in a free manner. The nonvolatile semiconductor memory device 1 is a nonvolatile semiconductor memory device that can retain the stored content even when the power is turned off.

In the nonvolatile semiconductor memory device 1, a back gate BG is provided above the substrate 10 via a not-shown insulating layer. The substrate 10 and the insulating layer are collectively referred to as an underlayer. In the substrate 10, active elements such as transistors and passive elements such as resistances and capacitances are provided. The back gate BG is, for example, a silicon (Si) layer doped with an impurity element to have electrical conductivity. A semiconductor layer (boron-doped silicon layer) 11 shown in FIG. 8 corresponds to the back gate BG. The structure of the neighborhood of the back gate BG will be described in detail using other drawings.

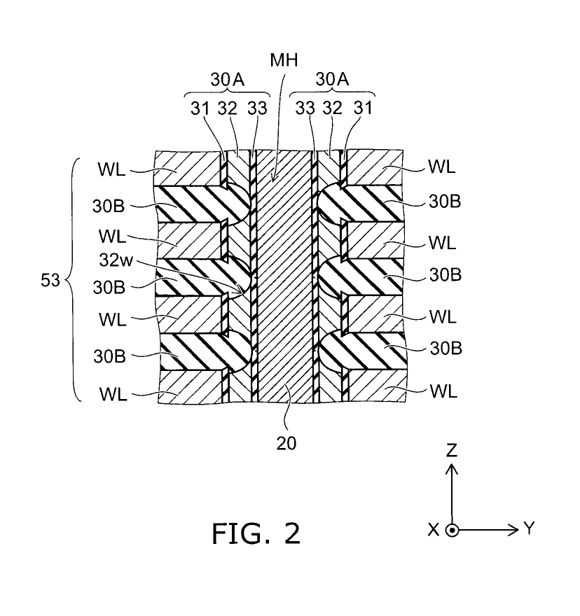

Above the back gate BG, each of a plurality of insulating layers 30B (see FIG. 2) and each of a plurality of control gate layers (or electrode layers) WL1D, WL2D, WL3D, WL4D, WL1S, WL2S, WL3S, and WL4S are alternately stacked.

The control gate layer WL1D and the control gate layer WL1S are provided at the same level, and appear as the control gate layers of the first layers from the bottom. The control gate layer WL2D and the control gate layer WL2S are provided at the same level, and appear as the control gate layers of the second layers from the bottom. The control gate layer WL3D and the control gate layer WL3S are provided at the same level, and appear as the control gate layers of the third layers from the bottom. The control gate layer WL4D and the control gate layer WL4S are provided at the same level, and appear as the control gate layers of the fourth layers from the bottom.

The control gate layer WL1D and the control gate layer WL1S are divided in the Y direction. The control gate layer WL2D and the control gate layer WL2S are divided in the Y direction. The control gate layer WL3D and the control gate layer WL3S are divided in the Y direction. The control gate layer WL4D and the control gate layer WL4S are divided in the Y direction.

An insulating layer 30B shown in FIG. 8 is provided between the control gate layer WL1D and the control gate layer WL1S, between the control gate layer WL2D and the control gate layer WL2S, between the control gate layer WL3D and the control gate layer WL3S, and between the control gate layer WL4D and the control gate layer WL4S.

The control gate layers WL1D, WL2D, WL3D, and WL4D are provided between the back gate BG and a drain-side select gate SGD. The control gate layers WL1S, WL2S, WL3S, and WL4S are provided between the back gate BG and a source-side select gate SGS.

The number of control gate layers WL1D, WL2D, WL3D, WL4D, WL1S, WL2S, WL3S, and WL4S is arbitrary. The number of layers is not limited to four illustrated in FIG. 1. In the following description, the control gate layers WL1D, WL2D, WL3D, WL4D, WL1S, WL2S, WL3S, and WL4S may be referred to as simply a control gate layer WL. The control gate layer WL is, for example, a p-type polysilicon layer doped with a p-type impurity to have electrical conductivity.

The drain-side select gate SGD is provided above the control gate layer WL4D via a not-shown insulating layer. The drain-side select gate SGD is, for example, a silicon layer doped with an impurity to have electrical conductivity.

The source-side select gate SGS is provided above the control gate layer WL4S via a not-shown insulating layer. The source-side select gate SGS is, for example, a silicon layer doped with an impurity to have electrical conductivity.

The drain-side select gate SGD and the source-side select gate SGS are divided in the Y direction. In the following description, the drain-side select gate SGD and the source-side select gate SGS may not be distinguished, and may be referred to as simply a select gate SG.

A source line SL is provided above the source-side select gate SGS via a not-shown insulating layer. The source line SL is, for example, a metal layer or a silicon layer doped with an impurity to have electrical conductivity.

A plurality of bit lines BL are provided above the drain-side select gate SGD and the source line SL via a not-shown insulating layer. Each bit line BL extends in the Y direction.

A plurality of U-shaped memory holes MH are formed in the back gate BG and a stacked body on the back gate BG. The memory hole MH also has a circular cylindrical shape. For example, in the control gate layers WL1D to WL4D and the drain-side select gate SGD, a hole penetrates through them and extends in the Z direction. In the control gate layers WL1S to WL4S and the source-side select gate SGS, a hole penetrates through them and extends in the Z direction. The one pair of holes extending in the Z direction are connected via a recess (space) formed in an area of the back gate BG. Therefore, the memory hole MH constitutes the U-shaped memory hole.

A channel body layer 20 is provided, in a U-shaped configuration, in the memory hole MH. The channel body layer 20 is, for example, a silicon layer. A stacked film 30A is provided between the channel body layer 20 and the inner wall of the memory hole MH. The stacked film 30A has a stacked structure of a block insulating layer/a floating gate layer/a tunnel insulating layer.

A gate insulating film 35 is provided between a channel body layer 51 connected to the channel body layer 20 and the drain-side select gate SGD. The channel body layer 51 is, for example, a silicon layer. A gate insulating film 36 is provided between the channel body layer 51 and the source-side select gate SGS.

The configuration is not limited to those in which the entire interior of the memory hole MH is filled with the channel body layer 20. For example, a structure is possible in which a hollow portion remains on the central axis side of the memory hole MH and an insulating material is buried in the hollow portion thereinside in the memory hole MH.

The drain-side select gate SGD, the channel body layer 51, and the gate insulating film 35 between the drain-side select gate SGD and the channel body layer 51 constitute a drain-side select transistor STD. The channel body layer 51 above the drain-side select transistor STD is connected to the bit line BL.

The source-side select gate SGS, the channel body layer 51, and the gate insulating film 36 between the source-side select gate SGS and the channel body layer 51 constitute a source-side select transistor STS. The channel body layer 51 above the source-side select transistor STS is connected to the source line SL.

The back gate BG, the channel body layer 20 provided in the back gate BG, and the stacked film 30A provided in the back gate BG constitute a back gate transistor BGT.

A plurality of memory cells MC using the respective control gate layers WL4D to WL1D as the control gates are provided between the drain-side select transistor STD and the back gate transistor BGT. Similarly, a plurality of memory cells MC using the respective control gate layers WL1S to WL4S as the control gates are provided between the back gate transistor BGT and the source-side select transistor STS.

The plurality of memory cells MC, the drain-side select transistor STD, the back gate transistor BGT, and the source-side select transistor STS are connected in series through the channel body layer to constitute one U-shaped memory string MS.

One memory string MS includes a pair of columnar portions CL extending in the stacking direction of a stacked body including the plurality of control gate layers WL and a connection portion 21 embedded in the back gate BG and connecting the pair of columnar portions CL. The memory string MS is arranged in plural in the X direction and the Y direction; thereby, a plurality of memory cells are three-dimensionally provided in the X direction, the Y direction, and the Z direction.

The plurality of memory strings MS are provided on a memory cell array region in the substrate 10. A peripheral circuit that controls the memory cell array is provided in, for example, a portion around the memory cell array region of the substrate 10.

FIG. 2 is an enlarged cross-sectional view of a portion of the memory cells according to the first embodiment.

A stacked body 53 is provided on the underlayer described above. The stacked body 53 includes the plurality of control gate layers WL and the plurality of insulating layers, and each of the plurality of control gate layers WL and each of the plurality of insulating layers 30B are stacked alternately. The channel body layer 20 is provided in the memory hole MH penetrating through the stacked body 53 in the stacking direction (the direction in which the plurality of control gate layers WL and the plurality of insulating layers 30B are stacked) of the stacked body 53. The stacked film 30A is provided between each control gate layer WL and the channel body layer 20.

The stacked film 30A has a structure in which, for example, a block insulating layer 31/a floating gate layer 32/a tunnel insulating layer 33 are stacked in this order from the control gate layer WL side toward the channel body layer 20 side. The floating gate layer 32 is provided between each of the plurality of control gate layers WL and the channel body layer 20. The block insulating layer 31 is provided between each of the plurality of control gate layers WL and the floating gate layer 32. The tunnel insulating layer 33 is provided between the channel body layer 20 and the floating gate layer 32.

The thickness in the Z direction of the control gate layer WL is twice or more the thickness in the Y direction of the floating gate layer 32. The length of the boundary between the floating gate layer 32 and the block insulating layer 31 is shorter than the length of the boundary between the floating gate layer 32 and the tunnel insulating layer 33 in the cut surface obtained by cutting the channel body layer 20 (or a hole 70) in the stacking direction (the Z direction) of the stacked body 53 along the central axis of the channel body layer 20 (or the hole 70). The contact area, with which the floating gate layer 32 is in contact with the block insulating layer 31, is smaller than the contact area with which the floating gate layer 32 is in contact with the tunnel insulating layer 33. The side surface 32w of the floating gate layer 32 is a curved surface. The width of the floating gate layer 32 in the stacking direction becomes gradually wider from the block insulating layer 31 toward the tunnel insulating layer 33. In the position where the floating gate layer 32 and the block insulating layer 31 are in contact, the width of the floating gate layer 32 in the stacking direction is narrower than the width of the block insulating layer 31 in the stacking direction. That is, when a surface of the block insulating layer 31 in contact with the control gate layer WL is defined as a first major surface and a surface of the block insulating layer 31 in contact with the floating gate layer 32 is defined as a second major surface, the insulating layer 30B is in contact with part of the second major surface.

The floating gate layer 32 includes, for example, a non-doped polysilicon layer. The block insulating layer 31 is made of, for example, silicon oxide (SiO₂).

The channel body layer 20 functions as a channel of the transistor in the memory cell. The control gate layer WL functions as a control gate. The floating gate layer 32 functions as a data storage layer that stores a charge injected from the channel body layer 20. The tunnel insulating layer 33 serves as a potential barrier when a charge is injected from the channel body layer 20 into the floating gate layer 32 or when the charge stored in the floating gate layer 32 diffuses to the channel body 20. The block insulating layer 31 prevents the charge stored in the floating gate layer 32 from diffusing to the control gate layer WL. The memory cell MC with a structure in which the control gate surrounds the periphery of the channel is formed at the intersection of the channel body layer 20 and each control gate layer WL.

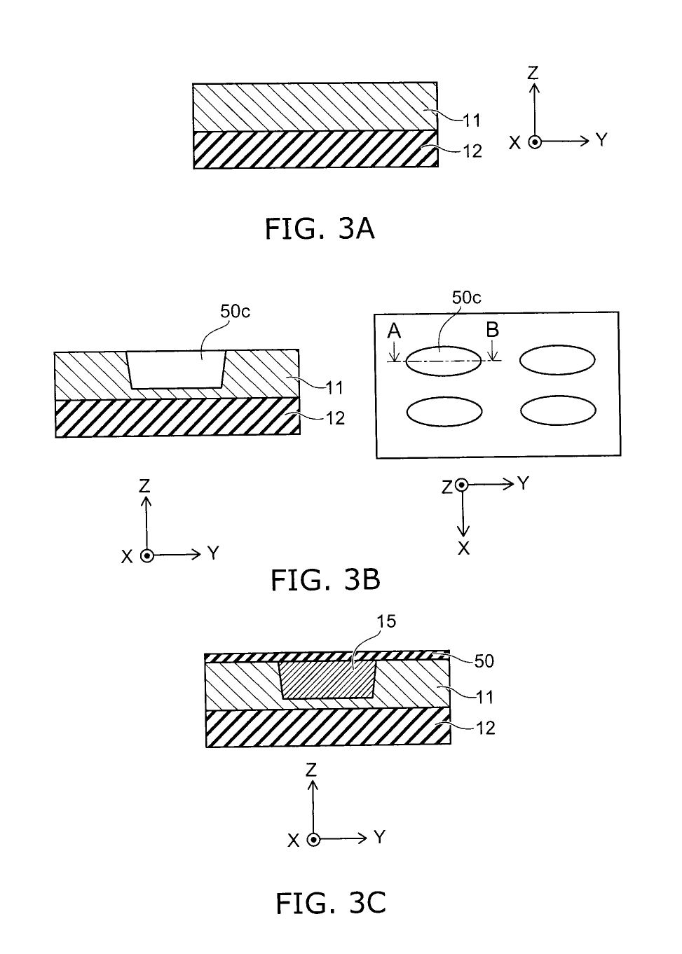

FIG. 3A to FIG. 8 are schematic cross-sectional views for describing manufacturing processes of the nonvolatile semiconductor memory device according to the first embodiment. FIG. 3B illustrates a schematic top view as well as a schematic cross-sectional view.

First, as shown in FIG. 3A, a first semiconductor layer 11 containing an impurity element is formed on an underlayer 12. The underlayer 12 includes, for example, transistors, interconnections of a peripheral circuit unit that controls memory cells, and interlayer insulating films, etc. The first semiconductor layer 11 is, for example, a boron-doped silicon layer. The boron-doped silicon layer forms the back gate BG.

Next, as shown in FIG. 3B, the surface of the first semiconductor layer 11 is selectively etched to form a recess 50c. Here, the left side of FIG. 3B is a schematic cross-sectional view, and the right side of FIG. 3B is a schematic top view. The schematic cross-sectional view of FIG. 3B is a cross-sectional view in a position along line A-B of the schematic top view.

For example, photolithography and RIE (reactive ion etching) are performed to form a plurality of recesses 50c from the surface to the inside of the first semiconductor layer 11. The plurality of recesses 50c are formed so as to be arranged in the X direction substantially parallel to the major surface (e.g. the upper surface or the lower surface) of the first semiconductor layer 11 and the Y direction substantially parallel to the major surface of the first semiconductor layer 11 and substantially perpendicular to the X direction. The position where the recess 50c is formed corresponds to the position of the connection portion 21 connecting the lower end of the memory hole MH to the first semiconductor layer 11. When the recess 50c is viewed from the Z direction, the outer shape thereof is elliptical, for example.

Next, as shown in FIG. 3C, a first sacrifice layer 15 is formed in each of the plurality of recesses 50c. The first sacrifice layer 15 is made of, for example, silicon nitride. The surplus portion of the first sacrifice layer 15 is removed as necessary by etchback to align the upper surface of the first sacrifice layer 15 with the upper surface of the first semiconductor layer 11.

Subsequently, an insulating layer 50 is formed on the first semiconductor layer 11 and on the first sacrifice layer 15. The insulating layer 50 is formed by, for example, CVD (chemical vapor deposition) using TEOS (tetraethoxysilane) as a material.

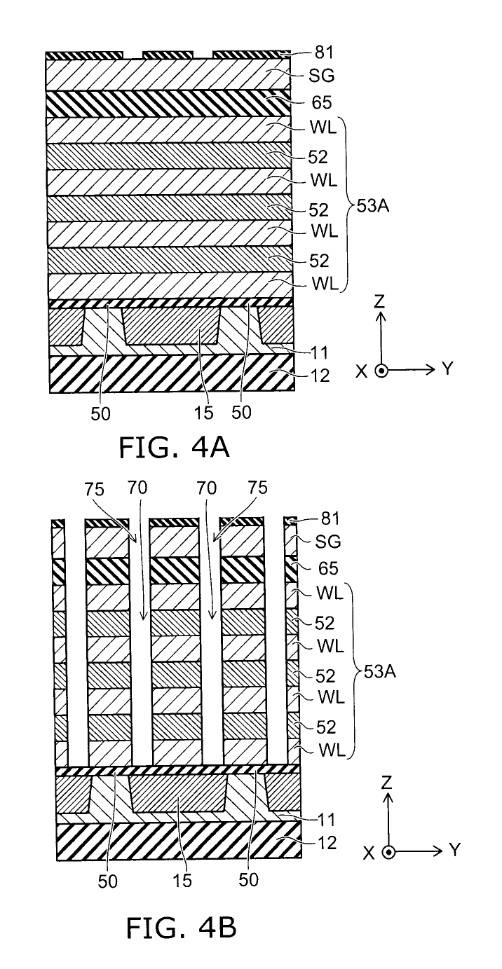

Next, as shown in FIG. 4A, a stacked body 53A including the plurality of control gate layers WL is formed on the insulating layer 50. The stacked body 53A includes the plurality of control gate layers WL and a second sacrifice layer 52 provided between adjacent ones of the plurality of control gate layers WL.

The stacked body 53A is a stacked body in which the control gate layer WL and the second sacrifice layer 52 are stacked in multiple stages. That is, each of the plurality of control gate layers WL and each of the plurality of second sacrifice layers are stacked alternately. The control gate layer WL is, for example, a boron-doped silicon layer. The control gate layer WL has a sufficient electrical conductivity as a gate electrode. The second sacrifice layer 52 is, for example, a non-doped silicon layer.

Further, an interlayer insulating film 65 is formed on the stacked body 53A, and the select gate SG is formed on the interlayer insulating film 65. Subsequently, a mask pattern 81 formed of a silicon oxide film is formed on the select gate SG.

Next, as shown in FIG. 4B, a pair of holes 70 extending from the surface of the stacked body 53A to the first sacrifice layer 15 and a hole 75 connected to each of the pair of holes 70 above the stacked body 53A are formed. For example, the select gate SG, the interlayer insulating film 65, and the stacked body 53A exposed from the mask pattern 81 are removed by dry etching such as RIE to form the pair of holes 70 and the hole 75 connected to each of the pair of holes 70.

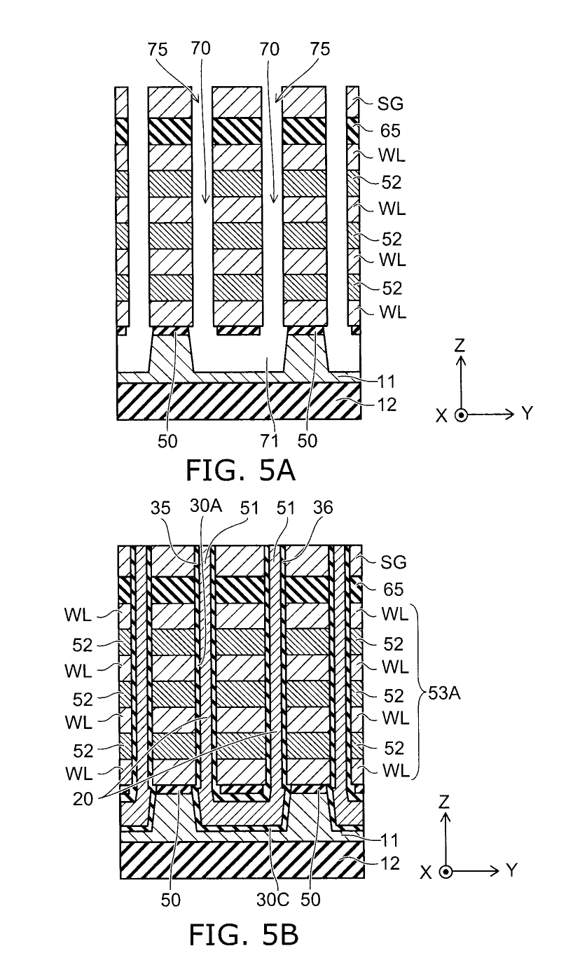

Next, as shown in FIG. 5A, the first sacrifice layer 15 is removed through the pair of holes 70 and the holes 75, and a first space 71 connected to the lower ends of the pair of holes 70 is formed in the first semiconductor layer 11. The first space 71 is formed from the surface to the inside of the first semiconductor layer 11. The removal of the first sacrifice layer 15 is performed by, for example, dissolving the first sacrifice layer 15 with a hot phosphoric acid solution. At this stage, the U-shaped memory hole MH, in which the lower ends of the pair of holes 70 and the first space 71 are connected, is formed.

Next, as shown in FIG. 5B, the stacked film 30A is formed on the side walls of the pair of holes 70 and the inner wall of the first space 71. Further, the channel body layer 20 is formed inside the stacked film 30A. That is, the block insulating layer 31, the floating gate layer 32, the tunnel insulating layer 33, and the channel body layer 20 are formed in this order from the side wall side of each of the pair of holes 70 and the inner wall side of the first space 71. The gate insulating films 35 and 36 are formed inside the hole 75. Further, simultaneously with forming the channel body layer 20, the channel body layer 51 is formed inside the gate insulating films 35 and 36 formed on the side wall of each of the holes 75. The channel body layer 20 and the channel body layer 51 are formed to be connected.

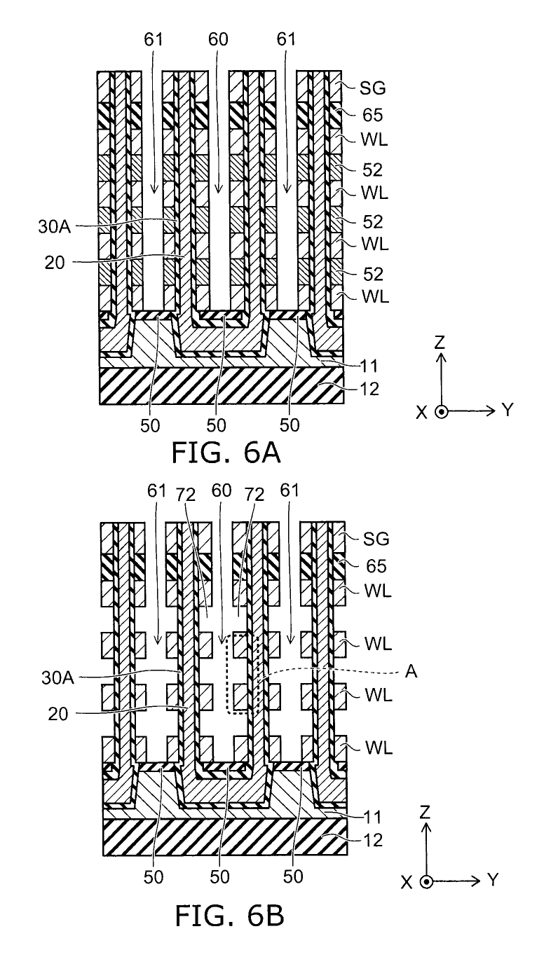

Next, as shown in FIG. 6A, a first slit 60 extending in a direction (the X direction) substantially perpendicular to the direction (the Y direction) in which the pair of holes 70 are aligned and a second slit 61 extending in the X direction likewise are formed.

For example, by dry etching such as RIE, the first slit 60 extending from the surface of the stacked body 53A to the insulating layer 50 is formed between the pair of holes 70, and the second slit 61 extending from the surface of the stacked body 53A to the insulating layer 50 is formed between pairs of holes 70 adjacent in the Y direction. When forming the first slit 60 and the second slit 61, the insulating layer 50 functions as an etching stop layer.

Next, as shown in FIG. 6B, the second sacrifice layer 52 is removed through the first slit 60 and the second slit 61. The removal of the second sacrifice layer 52 is performed by, for example, dissolving the second sacrifice layer 52 with an alkaline solution. Thereby, a second space 72 is formed between adjacent ones of the plurality of control gate layers WL.

After that, isotropic etching such as wet etching is performed to remove the block insulating layer 31 exposed at the second space 72 and remove the floating gate layer 32. The process is described using drawings in which the portion of the rectangular region A shown in FIG. 6B is enlarged.

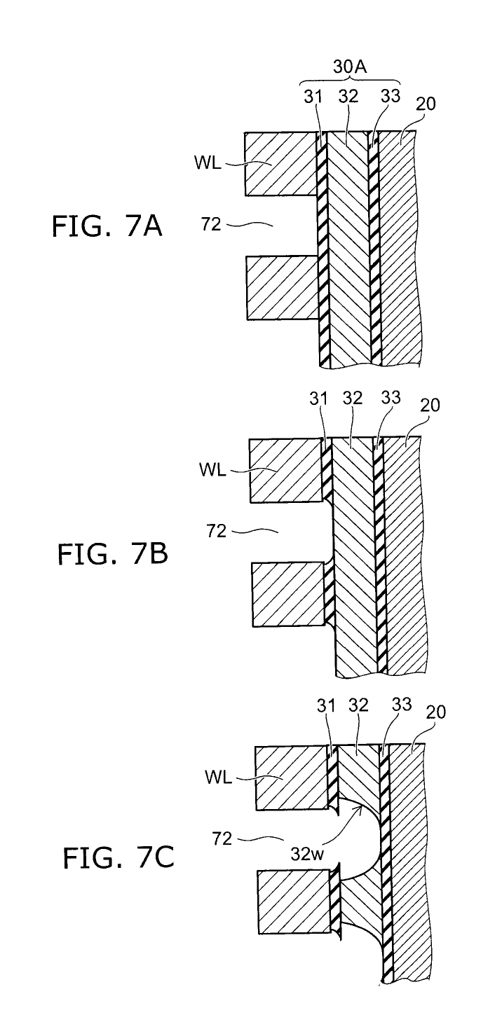

FIG. 7A shows the state shown in FIG. 6B. As shown in FIG. 7A, the second space 72 is formed between adjacent ones of the plurality of control gate layers WL. The block insulating layer 31 in the portion between adjacent ones of the plurality of control gate layers WL is exposed at the second space 72. At this stage, the floating gate layer 32 is in a state before processing. The continuous floating gate layer 32 before processing may be referred to as a second semiconductor layer 32.

Next, as shown in FIG. 7B, the block insulating layer 31 in the portion exposed at the second space 72 is removed. For example, the block insulating layer 31 in the portion exposed at the second space 72 is dipped in a dilute hydrofluoric acid solution to remove the block insulating layer 31 of this portion. A portion of the floating gate layer 32 located between adjacent ones of the plurality of control gate layers WL is exposed at the second space 72.

Next, the floating gate layer 32 in the portion exposed at the second space 72 is dipped in, for example, an alkaline aqueous solution. The floating gate layer 32 of the portion exposed at the second space 72 is removed, as shown in FIG. 7C. Then the floating gate layer 32 is formed between each of the plurality of control gate layers WL and the channel body layer 20.

In the first embodiment, since the floating gate layer 32 in the portion exposed at the second space 72 is removed by isotropic etching, the side surface 32w of the floating gate layer 32 after processing becomes a curved surface. Since the thickness of the control gate layer WL is twice or more the thickness of the floating gate layer 32, a structure is obtained in which the floating gate layer 32 after processing is in contact with the block insulating layer 31.

Next, as shown in FIG. 8, the insulating layer 30B is formed in the slits 60 and 61 and in the second space 72. In a portion above the memory cell MC, the drain-side select gate SGD and the source-side select gate SGS are formed. After that, other members (contact electrodes, interconnections, etc.) are formed; thus, the nonvolatile semiconductor memory device 1 is formed.

Thus, in the manufacturing processes of the nonvolatile semiconductor memory device 1, first, the first semiconductor layer 11 is formed on the underlayer 12. Next, the insulating layer 50 is formed on the first semiconductor layer 11. Next, a stacked body including the plurality of control gate layers WL and the sacrifice layer 52 provided between adjacent ones of the plurality of control gate layers WL is formed on the insulating layer 50. Next, the plurality of holes 70 extending from the surface of the stacked body to the first semiconductor layer 11 are formed. Next, the block insulating layer 31, the second semiconductor layer (the floating gate layer 32), the tunnel insulating layer 33, and the channel body layer 20 are formed in this order on the side wall of each of the plurality of holes 70. Next, the slits 60 and 61 extending in a direction parallel to the surface of the underlayer 12 and extending from the surface of the stacked body to the first semiconductor layer 11 are formed such that each of the plurality of holes 70 is partioned into each of the respective prescribed regions. Next, the sacrifice layer 52 is removed through the slits 60 and 61 to form the spaces 72, and each of the spaces 72 is formed between adjacent ones of the plurality of control gate layers WL. Next, the block insulating layer 31 exposed at each of the spaces 72 is partly removed to expose the second semiconductor layer (the floating gate layer 32) at each of the spaces 72. Next, the second semiconductor layer (the floating gate layer 32) exposed at each of the spaces 72 is partly removed to form a floating gate layer between each of the plurality of control gate layers WL and the channel body layer 20.

### Comparative Example

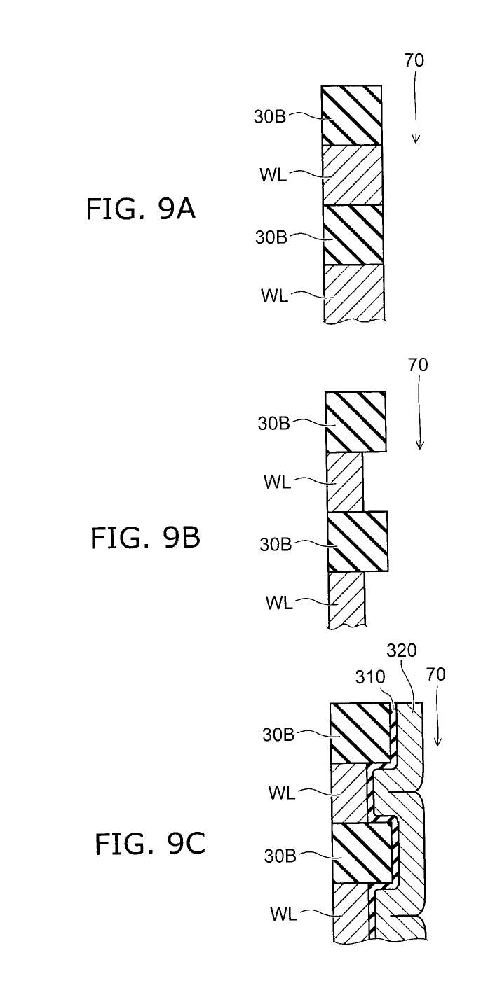

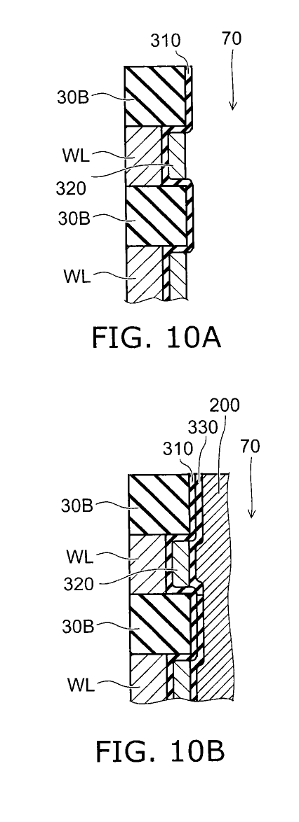

FIG. 9A to FIG. 10B are schematic cross-sectional views for describing manufacturing processes of a memory cell according to a comparative example.

First, as shown in FIG. 9A, a stacked body in which each of the control gate layers WL and each of the insulating layers 30B are alternately stacked is formed on an underlayer (not shown). Subsequently, the hole 70 is formed in the stacked body. Thereby, the side surface of the control gate layer WL and the side surface of the insulating layer 30B are exposed at the hole 70.

Next, as shown in FIG. 9B, an etchant for the control gate layer is introduced into the hole 70 to perform wet etching, and thereby the side surface of the control gate layer WL is recessed.

Next, as shown in FIG. 9C, a gas for deposition is introduced into the hole 70 to form a block insulating layer 310 on the side surface of the control gate layer WL and the side surface of the insulating layer 30B. Subsequently, a floating gate layer 320 is formed on the block insulating layer 310.

Next, as shown in FIG. 10A, the floating gate layer 320 is etched back, and the floating gate layer 320 faces only to the side surface of the control gate layer WL via the block insulating layer 310.

After that, as shown in FIG. 10B, a tunnel insulating layer 330 and a channel body layer 200 are formed on the block insulating layer 310 and on the floating gate layer 320 to form a memory cell.

In the comparative example, in order to face the floating gate layer 320 only to the side surface of the control gate layer WL, a process is passed through in which the continuous floating gate layer 320 is etched back to divide the continuous floating gate layer 320. Therefore, the film thickness control of the floating gate layer 320 facing to the side surface of the control gate layer WL is difficult. Thus, after the memory cell is formed, the film thicknesses of the plurality of floating gate layers 320 may vary. If the film thicknesses of the plurality of floating gate layers 320 vary, process conditions, the design of the memory cell, etc. are adversely affected. For example, it is necessary to deposit the floating gate layer 320 thick beforehand in accordance with the degree of the variation in the film thickness. Furthermore, in accordance with this, it is necessary to design the memory hole diameter large. Therefore, the downsizing of the memory cell becomes difficult.

In contrast, the first embodiment does not pass through the process in which the floating gate layer 32 is etched back. In the first embodiment, the film thickness of each of the plurality of floating gate layers 32 is determined just by the film thickness of the floating gate layer 32 when the floating gate layer 32 is deposited. Therefore, in the memory cell of the first embodiment, the film thicknesses of the plurality of floating gate layers 32 are less likely to vary than in the comparative example. In the first embodiment, since there is no etchback process of the floating gate layer 32, the memory hole diameter can be made smaller accordingly than that of the comparative example. Thereby, the downsizing of the memory cell becomes possible.

In the nonvolatile semiconductor memory device 1, the contact area with which the floating gate layer 32 is in contact with the block insulating layer 31 is smaller than the contact area with which the floating gate layer 32 is in contact with the tunnel insulating layer 33. However, the perimeter of the block insulating layer 31 is longer than the perimeter of the tunnel insulating layer 33. Therefore, when the capacitance between the channel body layer 20 and the floating gate layer 32 is denoted by C1 and the capacitance between the floating gate layer 32 and the control gate layer WL is denoted by C2, the coupling ratio (C2/(C1+C2)) is within a desired range. Consequently, electrons are stored in the floating gate layer 32 with good efficiency.

### Second Embodiment

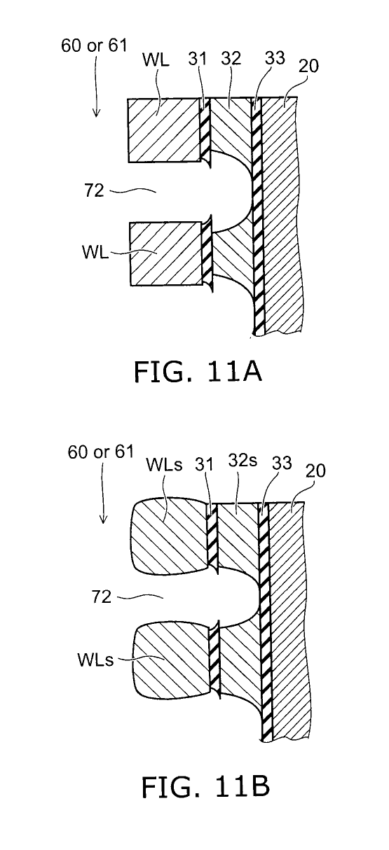

FIGS. 11A and 11B are schematic cross-sectional views for describing manufacturing processes of a nonvolatile semiconductor memory device according to a second embodiment.

FIG. 11A shows the state shown in FIG. 7C. In this state, since each of the control gate layers WL and the floating gate layer 32 are exposed at the second space 72, each of the plurality of control gate layers WL and the floating gate layer 32 can be simultaneously silicided.

For example, a metal-containing gas containing a metal such as nickel (Ni) is introduced into each of the second spaces 72 through the slits 60 and 61 to form a metal film on the surface of the control gate layer WL and the side surface of the floating gate layer 32. After that, by performing RTA (rapid thermal anneal) on the control gate layer WL and the floating gate layer 32, the metal is diffused from the metal film to each of the plurality of control gate layers WL and the floating gate layer 32.

Thereby, a silicided control gate layer WLs and a silicided floating gate layer 32s are formed. Each of the plurality of control gate layers WLs and the floating gate layer 32s include an alloy layer containing the metal and silicon.

In the second embodiment, since the floating gate layer includes a metal, the thickness of the floating gate layer can be made thinner than in the first embodiment. Thereby, the memory cell MC is more downsized. Furthermore, the variation in the threshold of the memory cell is more reduced. Furthermore, the etching processing thereof becomes easier due to the decrease in the film thickness of the floating gate layer. Moreover, as the floating gate layer becomes thinner, electrical interference between floating gate layers adjacent in the vertical direction is suppressed.

The work function of the floating gate layer 32s of the second embodiment is larger than the work function of the floating gate layer 32 of the first embodiment. Consequently, the floating gate layer 32s has an increased capability of capturing electrons introduced from the channel body layer 20. Thereby, in the nonvolatile semiconductor memory device of the second embodiment, data writing efficiency increases more. Furthermore, the electrons stored in the floating gate 32s are less likely to flow away to the channel body layer 20 side via the tunnel insulating layer 33. As a consequence, in the second embodiment, data retention improves as compared to the first embodiment.

### Third Embodiment

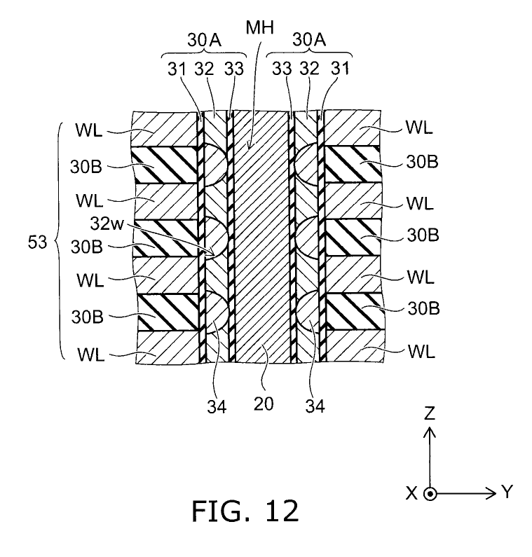

FIG. 12 is an enlarged cross-sectional view of a portion of memory cells according to a third embodiment.

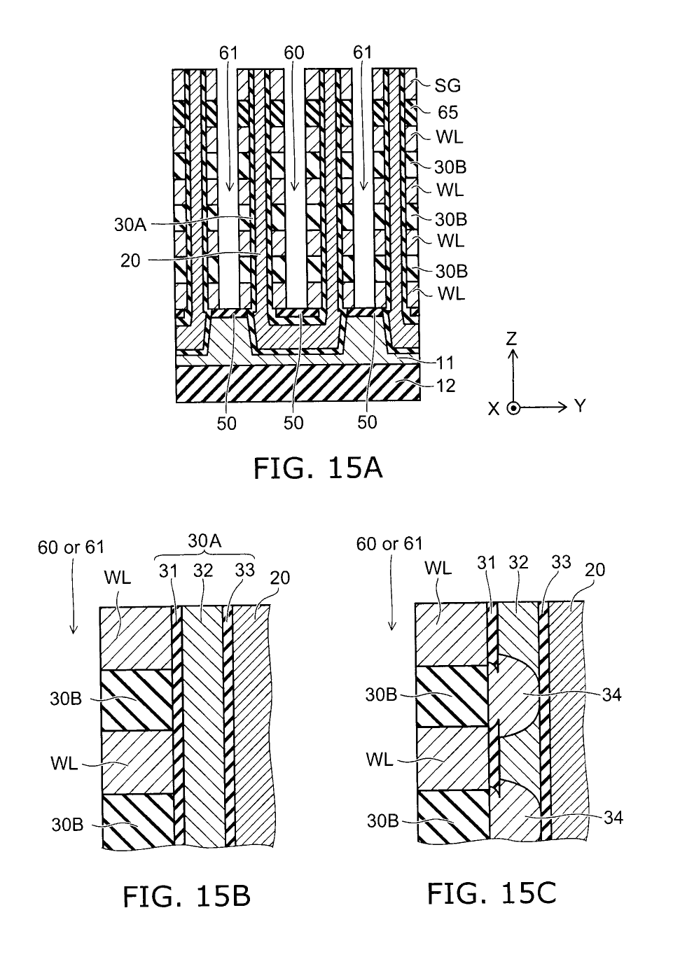

The structure of the memory cell of the third embodiment is substantially the same as the structure of the memory cell shown in FIG. 2. However, in the memory cell of the third embodiment, each of the plurality of insulating layers 30B contains hafnium oxide (HfO₂). Zirconium oxide (ZrO₂) may be used instead of hafnium oxide. The block insulating layer 31 is continuous in the stacking direction of the stacked body 53. An oxidized layer 34 is provided between adjacent floating gate layers 32. That is, the memory cell of the third embodiment further includes the oxidized layer 34 between each of the plurality of insulating layers 30B and the channel body layer 20, and the block insulating layer 31 is provided between each of the plurality of insulating layers 30B and the oxidized layer 34. As shown in FIG. 15C described later, the block insulating layer 31 may be discontinuous between adjacent ones of the plurality of control gate layers WL.

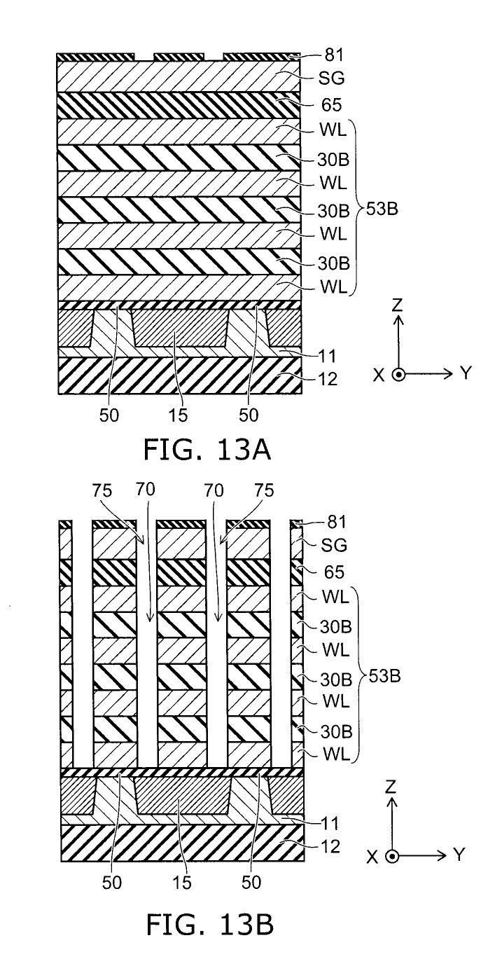

FIG. 13A to FIG. 15C are schematic cross-sectional views for describing manufacturing processes of a nonvolatile semiconductor memory device according to the third embodiment. In the following description, manufacturing processes similar to the manufacturing processes of the first embodiment are omitted as necessary.

As shown in FIG. 13A, the first semiconductor layer 11 is formed on the underlayer 12, the first sacrifice layer 15 is selectively formed from the surface to the inside of the first semiconductor layer 11, and the insulating layer 50 is formed on the first semiconductor layer 11 and on the first sacrifice layer 15.

Subsequently, a stacked body 53B including the plurality of control gate layers WL and the plurality of insulating layers 30B provided between adjacent ones of the plurality of control gate layers is formed on the insulating layer 50. That is, each of the plurality of control gate layers WL and each of the plurality of insulating layers 30B are stacked alternately. The insulating layer 30B is, for example, a hafnium oxide-containing layer or a zirconium oxide-containing layer.

Further, the interlayer insulating film 65 is formed on the stacked body 53B, and the select gate SG is formed on the interlayer insulating film 65. Subsequently, the mask pattern 81 made of a silicon oxide film is formed on the select gate SG.

Next, as shown in FIG. 13B, a pair of holes 70 extending from the surface of the stacked body 53B to the first sacrifice layer 15 are formed.

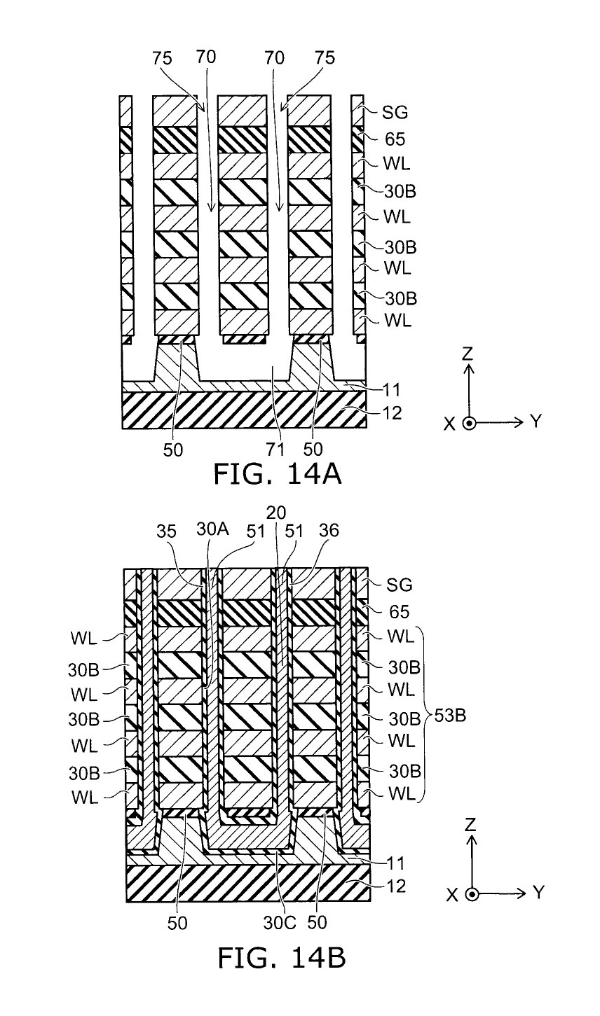

Next, as shown in FIG. 14A, the first sacrifice layer 15 is removed through the pair of holes 70, and the first space 71 connected to the lower ends of the pair of holes 70 is formed from the surface to the inside of the first semiconductor layer 11.

Next, as shown in FIG. 14B, the stacked film 30A is formed on the side walls of the pair of holes 70 and the inner wall of the first space 71. Further, the channel body layer 20 is formed inside the stacked film 30A. That is, the block insulating layer 31, the floating gate layer 32, the tunnel insulating layer 33, and the channel body layer 20 are formed in this order from the side wall side of each of the pair of holes 70 and the inner wall side of the first space 71.

Next, as shown in FIG. 15A, the first slit 60 extending in a direction (the X direction) substantially perpendicular to the direction (the Y direction) in which the pair of holes 70 are aligned and the second slit 61 extending in the X direction likewise are formed.

For example, the first slit 60 extending from the surface of the stacked body 53A to the insulating layer 50 is formed between the pair of holes 70, and the second slit 61 extending from the surface of the stacked body 53A to the insulating layer 50 is formed between pairs of holes 70 adjacent in the Y direction.

Next, as shown in FIG. 15B, an oxidizing gas (e.g. oxygen, ozone, ions thereof, or active oxygen such as radicals) is introduced into the first slit 60 and into the second slit 61. When the oxidizing gas is introduced, by the catalytic action of HfO₂ etc., a portion of the floating gate layer 32 facing to the insulating layer 30B via the block insulating layer 31 is oxidized. Heating treatment may be performed as necessary.

In this case, oxygen diffuses from the slit into the insulating layer 30B, and the floating gate layer 32 is oxidized. For example, when the thickness of the block insulating layer 31 is several nanometers (nm), a portion of the floating gate layer 32 facing to the insulating layer 30B via the block insulating layer 31 is oxidized. The cross-sectional configuration of the floating gate layer 32 becomes substantially the same as that in the case of wet etching described in the first embodiment.

Thereby, as shown in FIG. 15C, the floating gate layer 32 is formed between each of the plurality of control gate layers WL and the channel body layer 20. The oxidized layer 34 is formed between adjacent floating gate layers 32. FIG. 15C shows a state where the block insulating layer 31 that has been in contact with each of the plurality of control gate layers WL is joined to the oxidized layer 34 into one body, and the insulating layer 30B and the oxidized layer 34 are in contact. Depending on the degree of oxidation progress of the oxidized layer 34, even after the oxidized layer 34 is formed, as shown in FIG. 12 there is a case where the block insulating layer 31 remains between the insulating layer 30B and the oxidized layer 34, and the block insulating layer 31 keeps a continuous state in the stacking direction. After that, as shown in FIG. 8, the insulating layer 30B is formed in the slits 60 and 61.

The third embodiment exhibits similar effects to the first embodiment. In the third embodiment, the process of removing the second sacrifice layer 52 is eliminated, and manufacturing processes are simplified.

### Modification Example of the Third Embodiment

In the example of the third embodiment described above, the surface of the gate electrode layer WL may be corroded by the oxidized film through the catalytic action of the insulating layer 30B. In a modification example of the third embodiment, the corrosion is reliably suppressed.

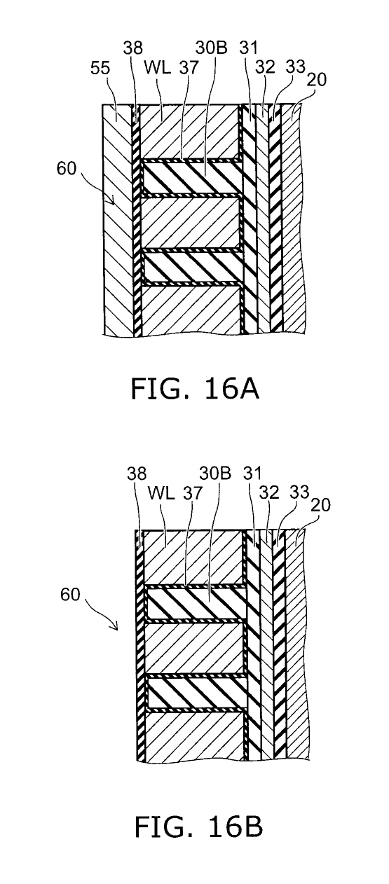

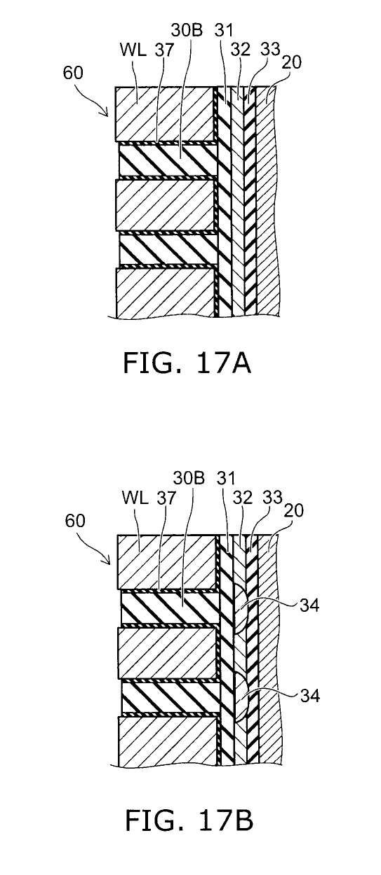

FIG. 16A to FIG. 17B are schematic cross-sectional views for describing manufacturing processes of a nonvolatile semiconductor memory device according to a modification example of the third embodiment.

In the modification example, in the state shown in FIG. 5A, the second sacrifice layer 52 is removed through the hole 70. The removal of the second sacrifice layer 52 is performed by, for example, introducing an alkaline solution into the hole 70 to dissolve the second sacrifice layer 52.

After that, in the hole 70, a barrier layer 37 including a silicon nitride film, the insulating layer 30B, the floating gate layer 32, the tunnel insulating layer 33, and the channel body layer 20 are formed in this order. FIG. 16A shows this state.

The block insulating layer 31 is made of the same material as the insulating layer 30B. That is, by the formation of the insulating layer 30B, the block insulating layer 31 is simultaneously formed. In the modification example, before forming the hole 70, the first slit 60 is formed beforehand and a non-doped amorphous silicon layer 55 is formed in the first slit 60 via a barrier layer 38. The barrier layer 38 is made of the same material as the barrier layer 37.

Next, as shown in FIG. 16B, the amorphous silicon layer 55 is removed by wet etching. Thereby, the first slit 60 is formed and the barrier layer 38 is exposed at the first slit 60.

Next, as shown in FIG. 17A, the barrier layer 38 is removed by wet etching. Subsequently, wet etching is performed to remove the barrier layer 37 in contact with the side surface of the insulating layer 30B. Thereby, the insulating layer 30B is exposed at the slit 60.

After that, as shown in FIG. 17B, an oxidizing gas (e.g. oxygen, ozone, ions thereof, or active oxygen such as radicals) is introduced into the first slit 60. Heating treatment may be performed as necessary. Thereby, a portion of the floating gate layer 32 facing to the insulating layer 30B via the block insulating layer 31 is oxidized to form the oxidized layer 34. In the modification example of the third embodiment, a barrier layer 37 is provided between the plurality of control gate layers WL and the plurality of insulating layers 30B.

By such manufacturing processes, the surface of the gate electrode layer WL is prevented from being corroded by the oxidized film.

### Fourth Embodiment

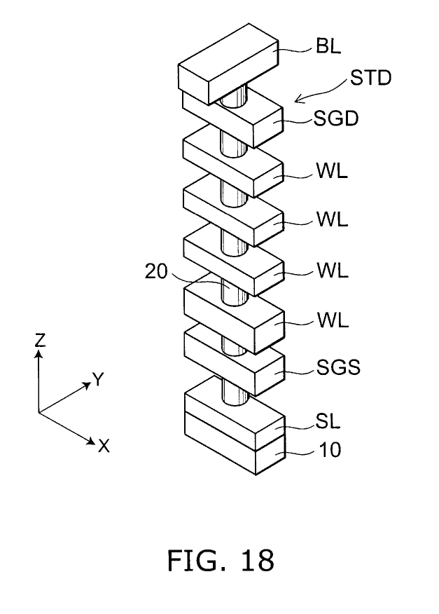

FIG. 18 is a schematic perspective view for describing a nonvolatile semiconductor memory device according to a fourth embodiment.

The memory string is not limited to the U-shaped configuration, but may be an I-shaped configuration as shown in FIG. 18. FIG. 18 shows only the conductive portions, and omits the insulating portions.

In this structure, the source line SL is provided on the substrate 10, the source-side select gate (or a lower select gate) SGS is provided thereabove, a plurality of (e.g. four) control gate layers WL are provided thereabove, and the drain-side select gate (or an upper select gate) SGD is provided between the uppermost control gate layer WL and the bit line BL.

In the structure, the processes and structures described above are applied to the drain-side select transistor STD provided at the upper end of the memory string.

Hereinabove, embodiments are described with reference to specific examples. However, the embodiment is not limited to these specific examples. That is, one skilled in the art may appropriately make design modifications to these specific examples, and such modifications also are included in the scope of the embodiment to the extent that the spirit of the embodiment is included. The components of the specific examples described above and the arrangement, material, conditions, shape, size, etc. thereof are not limited to those illustrated but may be appropriately altered.

Furthermore, the components of the embodiments described above may be combined within the extent of technical feasibility, and combinations of them also are included in the scope of the embodiment to the extent that the spirit of the embodiment is included. Furthermore, one skilled in the art may arrive at various alterations and modifications within the idea of the embodiment. Such alterations and modifications should be seen as within the scope of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
an underlayer;
a stacked body provided on the underlayer and including a plurality of control gate layers and a plurality of insulating layers, and each of the plurality of control gate layers and each of the plurality of insulating layers being stacked alternately;
a channel body layer penetrating through the stacked body in a stacking direction in which the plurality of control gate layers and the plurality of insulating layers are stacked;
a floating gate layer provided between each of the plurality of control gate layers and the channel body layer;
a block insulating layer provided between each of the plurality of control gate layers and the floating gate layer; and
a tunnel insulating layer provided between the channel body layer and the floating gate layer,
a length of a boundary between the floating gate layer and the block insulating layer being shorter than a length of a boundary between the floating gate layer and the tunnel insulating layer in a cut surface obtained by cutting the channel body layer in the stacking direction along a central axis of the channel body layer.

2. The device according to claim 1, wherein a first contact area is smaller than a second contact area, the floating gate layer is in contact with the block insulating layer with the first contact area, and the floating gate layer is in contact with the tunnel insulating layer with the second contact area.

3. The device according to claim 1, wherein a side surface of the floating gate layer forms a curved surface.

4. The device according to claim 1, wherein a width of the floating gate layer in the stacking direction becomes gradually wider from the block insulating layer toward the tunnel insulating layer.

5. The device according to claim 1, wherein a width of the floating gate layer in the stacking direction is narrower than a width of the block insulating layer in the stacking direction in a position where the floating gate layer and the block insulating layer are in contact.

6. The device according to claim 1, further comprising an oxidized layer between each of the plurality of insulating layers and the channel body layer.

7. The device according to claim 6, wherein the block insulating layer is provided between each of the plurality of insulating layers and the oxidized layer.

8. The device according to claim 1, further comprising a barrier layer between the plurality of control gate layers and the plurality of insulating layers.

9. The device according to claim 1, wherein the floating gate layer includes a polysilicon layer.

10. The device according to claim 1, wherein each of the plurality of control gate layers and the floating gate layer includes an alloy containing a metal and silicon.

11. The device according to claim 1, wherein each of the plurality of insulating layers contains hafnium oxide.

12. A method for manufacturing a nonvolatile semiconductor memory device comprising:
forming a first semiconductor layer on an underlayer;
forming a first insulating layer on the first semiconductor layer;
forming a stacked body on the first insulating layer, the stacked body including a plurality of control gate layers and a plurality of sacrifice layers, and each of the plurality of control gate layers and each of the plurality of sacrifice layers being stacked alternately;
forming a plurality of holes extending from a surface of the stacked body to the first semiconductor layer;
forming a block insulating layer, a second semiconductor layer, a tunnel insulating layer, and a channel body layer in this order on a side wall of each of the plurality of holes;
forming a plurality of slits extending from a surface of the stacked body to the first semiconductor layer to partition each of the plurality of holes into each of respective prescribed regions;
removing the sacrifice layers through the plurality of slits to form spaces, and each of the spaces being formed between adjacent ones of the plurality of control gate layers;
removing the block insulating layer exposed at the each of spaces partly to expose the second semiconductor layer at the each of spaces; and
removing the second semiconductor layer exposed at the each of spaces partly to form a floating gate layer between each of the plurality of control gate layers and the channel body layer.

13. The method according to claim 12, wherein isotropic etching is used to remove the block insulating layer and remove the second semiconductor layer.

14. The method according to claim 12, wherein a metal is diffused to each of the plurality of control gate layers and the floating gate layer after the floating gate layer is formed.

15. The method according to claim 14, wherein a metal film containing the metal is formed on a surface of each of the plurality of control gate layers and a surface of the floating gate layer by introducing a metal-containing gas into the spaces through the slits before the metal is diffused.

16. The method according to claim 15, wherein anneal treatment is performed on each of the control gate layers and the floating gate layer after the metal film is formed.

17. The method according to claim 12, wherein a second insulating layer is formed between adjacent ones of the plurality of control gate layers after the floating gate layer is formed.

18. A method for manufacturing a nonvolatile semiconductor memory device comprising:
forming a first semiconductor layer on an underlayer;
forming a first insulating layer on the first semiconductor layer;
forming a stacked body on the first insulating layer, the stacked body including a plurality of control gate layers and a plurality of second insulating layers, each of the plurality of control gate layers and each of the plurality of second insulating layers being stacked alternately, and the plurality of second insulating layers containing hafnium oxide;
forming a plurality of holes extending from a surface of the stacked body to the first semiconductor layer;
forming a block insulating layer, a second semiconductor layer, a tunnel insulating layer, and a channel body layer in this order on a side wall of each of the plurality of holes;
forming a plurality of slits extending from a surface of the stacked body to the first semiconductor layer to partition each of the plurality of holes into each of respective prescribed regions; and
forming a floating gate layer between each of the plurality of control gate layers and the channel body layer by introducing an oxidizing gas into the slits to partly oxidize the second semiconductor layer facing to the second insulating layer via the block insulating layer.

19. The method according to claim 18, wherein at least one of oxygen, ozone, an oxygen ion, an ozone ion, and an oxygen radical is selected as the oxidizing gas.

20. The method according to claim 18, wherein a barrier layer is formed between the plurality of control gate layers and the second insulating layer before the oxidizing gas is introduced.
